(19) United States
(12) Patent Application Publication
(10) Pub. No.: US 2026/0112849 A1
(43) Pub. Date: Apr. 23, 2026

(54) CONNECTOR ASSEMBLY, AND SUBSTRATE-PROCESSING APPARATUS COMPRISING SAME

(71) Applicant: PSK INC., Hwaseong-si, Gyeonggi-do (KR)

(72) Inventor: BUM SU PARK, Hwaseong-si, Gyeonggi-do (KR)

(21) Appl. No.: 18/706,748

(22) PCT Filed: Oct. 28, 2022
(86) PCT No.: PCT/KR2022/016639

§ 371 Date: Dec. 31, 2025

(30) Foreign Application Priority Data
Nov. 2, 2021 (KR) 10-2021-0149133

(51) Int. Cl. H01R 13/684; H01J 37/32; H01R 13/04

(52) U.S. Cl. CPC H01R 13/684; H01R 13/04; H01J 37/32

(57) ABSTRACT

The present invention provides a substrate-processing apparatus. The substrate-processing apparatus comprises: a housing having a processing space for processing a substrate; a support unit for supporting the substrate in the processing space; a plasma source for generating plasma using a process gas supplied to the processing space; and a connector assembly for supplying power to components provided in the apparatus, wherein the connector assembly may comprise a body having a groove formed on the outer surface thereof, a pin unit inserted into the groove, and a fuse installed in the pin unit.

### FIELD OF THE DISCLOSURE

The present invention relates to a connector assembly and a substrate processing apparatus including the same.

### BACKGROUND OF THE DISCLOSURE

In general, a connector assembly serves to electrically connect cables attached to respective ends. The connector assembly is widely used in industries, such as automotive, home appliances, or semiconductor manufacturing devices.

When an overcurrent flows through a connector assembly, the connector assembly generates heat. Heating of the connector assembly has the potential to cause a fire. In the event of an overcurrent flowing through the connector assembly, a circuit breaker exists to interrupt the current inside the connector assembly. However, the circuit breaker only takes follow-up measures to the overcurrent and/or heat that has already been generated in the connector assembly. In other words, the circuit breaker does not proactively prevent the overcurrent and/or heat from generating inside the connector assembly.

### SUMMARY OF THE DISCLOSURE

### Technical Problem

The present invention aims to provide a connector assembly and a substrate processing apparatus including the same that prevent a fire in a connector assembly and a substrate processing device including the connector assembly.

Further, the present invention aims to provide a connector assembly and a substrate processing apparatus including the same that prevent an overcurrent from flowing inside the connector assembly in advance.

Further, the present invention aims to provide a connector assembly and a substrate processing apparatus including the same that prevent heat generation inside the connector assembly in advance.

Further, the present invention aims to provide a connector assembly and a substrate processing apparatus including the same, in which a fuse is easily replaceable.

The problem to be solved by the present invention is not limited to the above-mentioned problems, and the problems not mentioned will be clearly understood by those skilled in the art from the present specification and the accompanying drawings.

### Technical Solution

An exemplary embodiment of the present invention provides an apparatus for processing a substrate, the apparatus including: a housing having a processing space for processing a substrate; a support unit for supporting a substrate in the processing space; a plasma source for generating plasma from process gas supplied to the processing space; and a connector assembly provided to supply power to a component provided in the apparatus, in which the connector assembly includes: a body having a groove formed on an external surface; a pin unit inserted into the groove; and a fuse installed in the pin unit.

According to the exemplary embodiment, the pin unit may be detachably provided on the body.

According to the exemplary embodiment, the fuse may be detachably provided on the pin.

According to the exemplary embodiment, the pin unit may include: a first portion into which an external first cable is inserted; and a second portion into which an external second cable is inserted, and the first portion may have a first through-hole into which a first lead wire of the fuse is inserted, and the second portion may have a second through-hole into which a second lead wire of the fuse is inserted.

According to the exemplary embodiment, the first portion and the second portion may be provided as conductors, and a third portion formed of an insulating material may be located between the first portion and the second portion.

According to the exemplary embodiment, the first portion may be provided in a cylindrical shape having a first diameter, and the second portion may be provided in a cylindrical shape having a second diameter smaller than the first diameter.

Another exemplary embodiment of the present invention provides a connector assembly including: a body having a groove formed on an external surface; a pin unit inserted into the groove; and a fuse installed in the pin unit, in which the pin unit is detachably provided on the body.

According to the exemplary embodiment, the fuse may be detachably provided on the pin.

According to the exemplary embodiment, the pin unit may include: a first portion into which an external first cable is inserted; and a second portion into which an external second cable is inserted, and the first portion may have a first through-hole into which a first lead wire of the fuse is inserted, and the second portion may have a second through-hole into which a second lead wire of the fuse is inserted.

According to the exemplary embodiment, the first portion and the second portion may be provided as conductors, and a third portion formed of an insulating material may be located between the first portion and the second portion.

According to the exemplary embodiment, the first portion may be provided in a cylindrical shape having a first diameter, and the second portion may be provided in a cylindrical shape having a second diameter smaller than the first diameter.

### Advantageous Effects

According to the exemplary embodiment of the present invention, it is possible to prevent a fire of the connector assembly and the substrate processing apparatus including the same in advance.

Further, according to the exemplary embodiment of the present invention, it is possible to prevent an overcurrent from flowing in the connector assembly and heat from being generated.

Further, according to the exemplary embodiment of the present invention, it is possible to easily perform maintenance work on the connector assembly.

Further, according to the exemplary embodiment of the present invention, it is possible to reduce maintenance costs of the connector assembly.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a diagram schematically illustrating a substrate processing apparatus according to an exemplary embodiment of the present invention.

FIG. 2 is a diagram schematically illustrating a process chamber performing a plasma treatment process among process chambers of the substrate processing apparatus of FIG. 1 according to the exemplary embodiment.

FIG. 3 is a perspective view schematically illustrating a view of a connector assembly provided in the substrate processing apparatus of FIG. 1.

FIG. 4 is a perspective view schematically illustrating a side view of the connector assembly of FIG. 3.

FIG. 5 is a schematic view of the connector assembly of FIG. 3 in which a pin unit and a fuse are removed from a body of the connector assembly of FIG. 3.

FIG. 6 is a diagram schematically illustrating the pin unit of FIG. 3, viewed from the side.

FIG. 7 is a diagram schematically illustrating the pin unit of FIG. 3 according to another exemplary embodiment.

### DETAILED DESCRIPTION OF THE EXEMPLARY EMBODIMENTS

Hereinafter, an exemplary embodiment of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

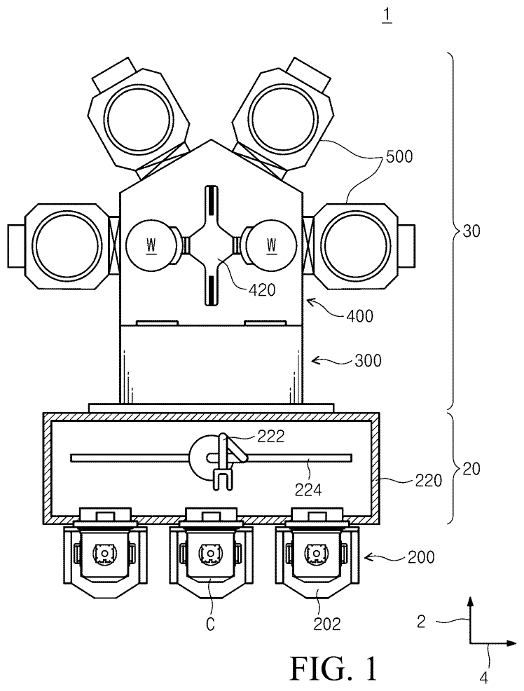

Hereinafter, an exemplary embodiment of the present invention will be described in detail with reference to FIGS. 1 to 7.

FIG. 1 is a diagram schematically illustrating a substrate processing apparatus of the present invention. Referring to FIG. 1, a substrate processing apparatus 1 includes an Equipment Front End Module (EFEM) 20 and a processing module 30. The EFEM 20 and the processing module 30 are disposed in one direction.

The equipment front end module 20 includes a load port 10 and a transfer frame 220. The load port 200 is disposed at the front of the equipment front end module 20 in a first direction 2. The load port 10 includes a plurality of support parts 202. Each support part 202 is arranged in a row in a second direction 4, on which a substrate W to be provided to the process and a carrier C (for example, cassette, or FOUP) in which the completely processed substrate W is accommodated are seated. In the carrier C, the substrate W to be provided to the process and the substrate W that has been completely processed are accommodated. The transfer frame 220 is disposed between the load port 200 and the processing module 30. The transfer frame 220 includes a first transfer robot 222 disposed therein and transferring the substrate W between the load port 200 and the processing module 30. The first transfer robot 222 moves along a transfer rail 224 provided in the second direction 4 to transfer the substrate W between the carrier C and the processing module 30.

The treating module 30 includes a load lock chamber 300, a transfer chamber 400, and a process chamber 500.

The load lock chamber 300 is disposed to be adjacent to the transfer frame 220. In one example, the load lock chamber 300 may be disposed between the transfer chamber 400 and the equipment front end module 20. The load lock chamber 300 provides a waiting area for substrates W to be provided to the process before they are transferred to the process chamber 500, or for substrates W that have completed process processing before they are transferred to the equipment front end module 20.

The transfer chamber 400 is disposed to be adjacent to the load lock chamber 300. The transfer chamber 400 has a polygonal body when viewed from above. In one example, the transfer chamber 400 may have a pentagonal body when viewed from above. On the outer side of the body, a load lock chamber 300 and a plurality of process chambers 500 are disposed along the circumstance of the body. A passage (not illustrated) through which the substrate W enters and exists is formed on each sidewall of the body, and the passage connects the transfer chamber 50 and the load lock chamber 300 or the process chambers 500. Each passage is provided with a door (not illustrated) which opens/closes the passage to seal the interior.

In the interior space of the transfer chamber 400, a second transfer robot 420 is arranged to transfer the substrate W between the load lock chamber 300 and the process chamber 500. The second transfer robot 420 transfers the unprocessed substrate W waiting in the load lock chamber 300 to the process chamber 500, or transfers the processed substrate W to the load lock chamber 300. Then, the substrate W is transferred between the process chambers 500 to sequentially provide the substrate W to the plurality of process chambers 500. In one example, as illustrated in FIG. 1, when the transfer chamber 400 has a pentagonal body, each load lock chamber 300 is disposed on the sidewall adjacent to the equipment front end module 20, and the process chambers 500 are sequentially disposed on the remaining sidewalls. The shape of the transfer chamber 400 is not limited to, and may be provided in various forms depending on the process module required.

The process chambers 500 are disposed along the circumference of the transfer chamber 400. The plurality of process chambers 500 may be provided. Within each process chamber 500, a process treatment is performed on the substrate W. The process chamber 500 receives the substrate W from the second transfer robot 420, processes the substrate W, and provides the processed substrate W to the second transfer robot 420. The process processing performed in the respective process chambers 500 may be different from each other.

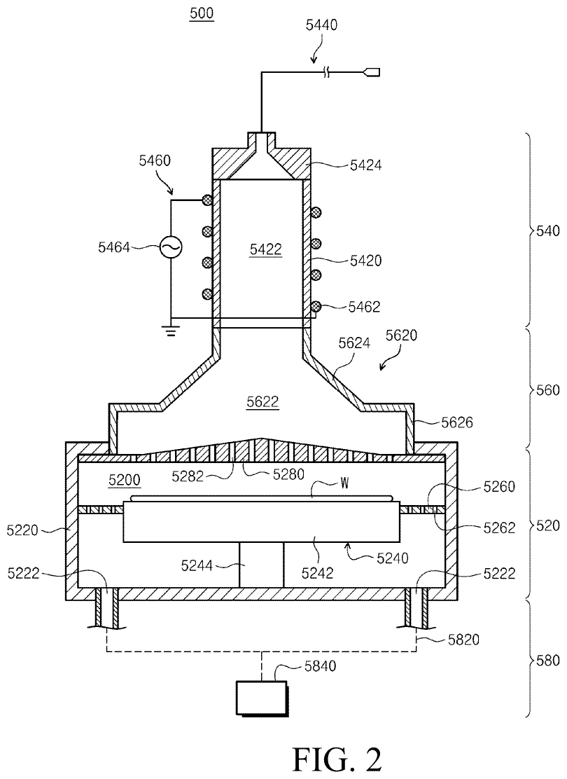

FIG. 2 is a diagram schematically illustrating the process chamber performing a plasma treatment process among the process chambers of the substrate processing apparatus of FIG. 1 according to the exemplary embodiment. Hereinafter, the process chamber 500 that performs a plasma treatment process will be described.

Referring to FIG. 2, the process chamber 500 performs a predetermined process on the substrate W by using plasma. In one example, a thin film on the substrate W may be etched or ashed. The thin film may be various types of films, such as a polysilicon film, an oxide film, or a silicon nitride film. Optionally, the thin film may be a natural oxide film or a chemically generated oxide film.

The process chamber 500 may include a process processing unit 520, a plasma generation unit 540, a diffusion unit 560, and an exhaust unit 580.

The process processing unit 520 provides a processing space 5200 where the substrate W is placed and where processing is performed on the substrate W. The plasma generation unit 540, which is described later, generates plasma by discharging process gas, and supplies the generated plasma to the processing space 5200 of the process processing unit 520. Process gas that remains inside the process processing unit 520 and/or reaction by-products generated in the process of processing the substrate W are discharged to the outside of the process chamber 500 through the exhaust unit 580, which will be described later. This allows the pressure within the process processing section 520 to be maintained at a set pressure.

The process processing unit 520 may include a housing 5220, a support unit 5240, an exhaust baffle 5260, and a baffle 5280.

The interior of the housing 5220 may be provided with a processing space 5200 for performing a substrate processing process. An outer wall of the housing 5220 may be provided as a conductor. In one example, the outer wall of the housing 5220 may be provided of a metal material including aluminum. The housing 5220 may be open at the top, and an opening (not illustrated) may be formed in the side wall. The substrate W enters and exits the interior of the housing 110 through the opening. The opening (not illustrated) may be opened and closed by an opening/closing member, such as a door (not illustrated). Additionally, an exhaust hole 5222 is formed in a bottom surface of the housing 5220.

The exhaust hole 5222 allows process gases and/or byproducts flowing within the processing space 5200 to be exhausted to the outside of the processing space 5200. The exhaust hole 5222 may be connected with the configurations including the exhaust unit 580 described later.

The support unit 5240 supports the substrate W in the processing space 5200. The support unit 5240 may include a support plate 5242 and a support shaft 5244. The support plate 5242 may be connected to an external power source. The support plate 5242 may generate static electricity by power applied from the external power source. The electrostatic force of the generated static electricity may hold the substrate W to the support unit 5240.

The support shaft 5244 may move a target object. For example, the support shaft 5244 may move the substrate W in an upward or downward direction. In one example, the support shaft 5244 may be coupled with the support plate 5244 and may raise and lower the support plate 5242 to move the substrate W up and down.

The exhaust baffle 5260 uniformly exhausts plasma from the processing space 5200 for each region. When viewed from above, the exhaust baffle 300 has an annular ring shape. The exhaust baffle 5260 may be positioned between the inner wall of the housing 5220 and the support unit 5240 within the processing space 5200. A plurality of exhaust holes 5262 is formed in the exhaust baffle 5260. The exhaust holes 5262 may be provided to face in an upward or downward direction. The exhaust holes 5262 may be provided as holes extending from a top end to a bottom end of the exhaust baffle 5260. The exhaust holes 5262 may be arranged to be spaced apart from each other along the circumferential direction of the exhaust baffle 5260.

The baffle 5280 may be disposed between the process processing unit 520 and the plasma generation unit 540. Further, the baffle 5280 may be disposed between the process processing unit 520 and the diffusion unit 560. Further, the baffle 5280 may be disposed between the support unit 5240 and the diffusion unit 560. The baffle 5280 may be disposed above the support unit 5240. In one example, the baffle 5280 may be disposed on the upper end of the process processing unit 520.

The baffle 5280 may uniformly deliver plasma generated by the plasma generation unit 540 into the processing space 5200. Baffle holes 5282 may be formed in the baffle 5280. The baffle holes 5282 may be provided in a plurality. The baffle holes 5282 may be spaced apart from each other. The baffle holes 5282 may penetrate the battle 5280 from the top end to the bottom end. The baffle holes 5282 may function as passageways for plasma generated in the plasma generation unit 540 to flow into the processing space 5200.

The baffle 5280 may have a plate shape. The baffle 5280 may have a disk shape when viewed from above. When viewed in cross-section, the baffle 5280 may have a height of its top surface that increases from an edge region to a center region. In one example, the baffle 5280 may have a shape such that its top surface slopes upwardly from the edge region to the center region when viewed in cross-section.

Accordingly, plasma generated by the plasma generation unit 540 may flow along the sloped cross-section of the baffle 5280 to the edge region of the processing space 5200. Unlike the examples described above, the cross-section of the baffle 5280 may not be provided to be sloped. In one example, the baffle 5280 may be provided in the shape of a disk having a predetermined thickness.

The plasma generation unit 540 may generate plasma by excitation of process gas supplied from the gas supply unit 5440, which will be described later, and supply the generated plasma into the processing space 5200.

The plasma generation unit 540 may be located above the process processing unit 520. The plasma generation unit 540 may be located above the housing 5220 and the diffusion section 560 which will be described later. The process processing unit 520, the diffusion unit 560, and the plasma generation unit 540 may be positioned sequentially from the ground along the third direction 6 perpendicular to both the first direction 2 and the second direction 4.

The plasma generation unit 540 may include a plasma chamber 5420, a gas supply unit 5440, and a power application unit 5460.

The plasma chamber 5420 may have a shape with an open upper surface and an open lower surface. In one example, the plasma chamber 5420 may have a cylindrical shape with an open top surface and an open bottom surface. Openings may be formed in the top end and the bottom end of the plasma chamber 5420. The plasma chamber 5420 may have a plasma generation space 5422. The plasma chamber 5420 may be provided with a material including aluminum oxide (Al2O3).

The top surface of the plasma chamber 5420 may be sealed by a gas supply port 5424. The gas supply port 5424 may be connected to a gas supply unit 5440, which will be described later. Process gas may be supplied to the plasma generation space 5422 through the gas supply port 5424. The process gas supplied to the plasma generation space 5422 may be uniformly distributed through the baffle holes 5282 into the processing space 5200.

The gas supply unit 5440 may supply the process gas. The gas supply unit 5440 may be connected to the gas supply port 5424. The process gas supplied by the gas supply unit 5440 may include fluorine and/or hydrogen.

The power application unit 5460 applies high frequency power to the plasma generation space 5422. The power application unit 5460 may be a plasma source that excites process gas in the plasma generation space 5422 to generate plasma. The power application unit 5460 may include an antenna 5462 and a power source 5464.

The antenna 5462 may be an Inductively Coupled Plasma (ICP) antenna. The antenna 5462 may be provided in a coil shape. The antenna 5462 may be wound around the plasma chamber 5420 multiple times in the outside of the plasma chamber 5420. The antenna 5462 may be wound around the plasma chamber 5420 in a spiral shape multiple times in the outside of the plasma chamber 5420.

The antenna 5462 may be wound around the plasma chamber 5420 in a region corresponding to the plasma generation space 5422. One end of the antenna 5462 may be provided at a height corresponding to an upper region of the plasma chamber 5420, as viewed from a right cross-section of the plasma chamber 5420. The other end of the antenna 5462 may be provided at a height corresponding to a lower region of the plasma chamber 5420, as viewed from right cross-section of the plasma chamber 5420.

The power source 5464 may apply power to the antenna 5462. The power source 5464 may apply a high frequency alternating current to the antenna 5462. The high frequency alternating current applied to the antenna 5462 may form an induced electric field in the plasma generation space 5422. The process gas supplied into the plasma generation space 5422 may obtain the energy required for ionization from the induced electric field and be converted to a plasma state.

The power source 5464 may be connected to one end of the antenna 5462. The power source 5464 may be connected to one end of the antenna 5462 provided at a height corresponding to the upper region of the plasma chamber 5420. Additionally, the other end of the antenna 5462 may be grounded. The other end of the antenna 5462, provided at the height corresponding to the lower region of the plasma chamber 5420, may be grounded. However, without limitation, one end of the antenna 5462 may be grounded and the power source 5464 may be connected to the other end of the antenna 5462.

The diffusion unit 560 may diffuse the plasma generated by the plasma generation unit 540 into the processing space 5200. The diffusion unit 560 may include a diffusion chamber 5620. The diffusion chamber 5620 includes a plasma diffusion space 5622 for diffusing the plasma generated in the plasma chamber 5420. The plasma generated in the plasma generation unit 540 may be diffused as it passes through the plasma diffusion space 5622. The plasma entering the plasma diffusion space 5622 may be uniformly distributed through the baffle 5280 and into the processing space 5200.

The diffusion chamber 5620 may be located below the plasma chamber 5420. The diffusion chamber 5620 may be located between the housing 5220 and the plasma chamber 5420. The housing 5220, the diffusion chamber 5620, and the plasma chamber 5420 may be positioned sequentially from the ground along the third direction 6. The inner circumferential surface of the diffusion chamber 5620 may be provided as a non-conductor. In one example, the inner circumferential surface of the diffusion chamber 5620 may be provided with a material including quartz.

The exhaust unit 580 may exhaust process gases and impurities inside the processing unit 520 to the outside. The exhaust unit 580 may exhaust impurities, particles, and the like generated during the process of processing the substrate W to the outside of the process chamber 500. The exhaust unit 580 may exhaust process gas supplied into the processing space 5200 to the outside of the process chamber 500. The exhaust unit 580 may include an exhaust line 5820 and a pressure reducing member 5840. The exhaust line 5820 may be connected to the exhaust holes 5222 formed in the bottom surface of the housing 5220. The exhaust line 5820 may be connected with the pressure reducing member 5840 to provide pressure reduction.

The pressure reducing member 5840 may provide negative pressure to the processing space 5200. The pressure reducing member 5840 may discharge plasma, impurities, particles, and the like that remain in the processing space 5200 to the outside of the housing 5220. Additionally, the pressure reducing member 5840 may provide negative pressure to maintain the pressure in the processing space 5200 at a predetermined pressure. The pressure reducing member 123 may be a pump. However, the pressure reducing member 5840 is not limited thereto, and may be provided with various variations of known devices that provide negative pressure.

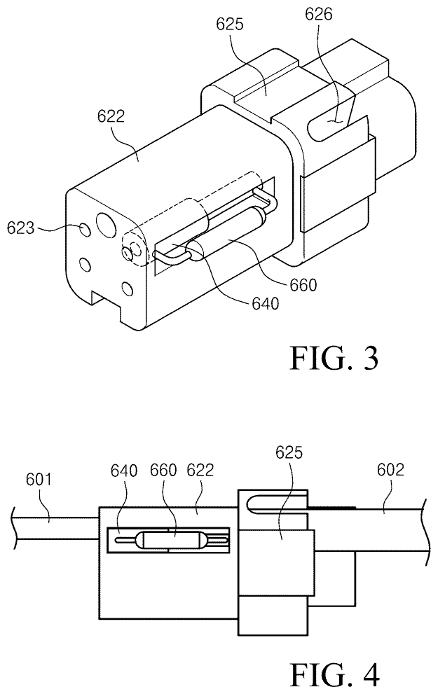

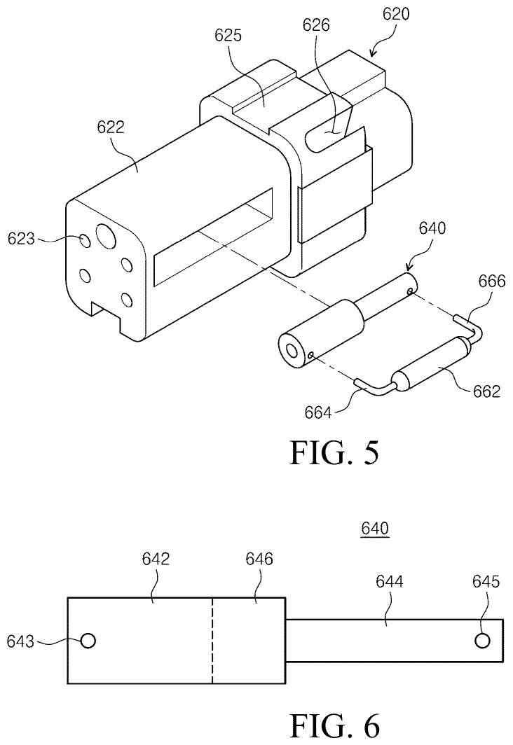

FIG. 3 is a perspective view schematically illustrating a view of a connector assembly provided in the substrate processing apparatus of FIG. 1. FIG. 4 is a perspective view schematically illustrating a side view of the connector assembly of FIG. 3. FIG. 5 is a schematic view of the connector assembly of FIG. 3 in which a pin unit and a fuse are removed from a body of the connector assembly of FIG. 3. FIG. 6 is a diagram schematically illustrating the pin unit of FIG. 3, viewed from the side. Hereinafter, a connector assembly according to an exemplary embodiment of the present invention will be described in detail.

Referring to FIGS. 3 and 4, the connector assembly 600 according to the exemplary embodiment of the present invention may be provided on a component provided to a substrate processing device 1. The connector assembly 600 may be provided to any component that requires power among the components provided to the substrate processing device 1. For example, the connector assembly 600 may be provided to components that require power among the components provided to the process chamber 500 according to the exemplary embodiment of the present invention.

The connector assembly 600 may connect power cables delivering power to each other. In one example, the connector assembly 600 may connect an external first cable 601 and an external second cable 602 delivering power to each other. However, the present invention is not limited thereto, and the connector assembly 600 may connect a plurality of cables that need to be electrically connected to each other. The connector assembly 600 may also connect signal cables transmitting control signals to each other. The connector assembly 600 may include a body 620, a pin unit 640, and a fuse 660.

The body 620 may form an exterior and a frame of the connector assembly 600. In the exemplary embodiment of the present invention, the body 620 may include a first body 622 and a second body 625. The first body 622 may function as an insertion part that may be connected to an external power source. In one example, the first cable 601 provided from an external power source may be inserted into the first body 622.

A first insertion groove 623 may be formed on one surface of the first body 622 into which the external first cable 601 may be inserted. The first insertion groove 623 may extend from the one surface of the first body 622 to the other surface facing the one surface of the first body 622. In one example, the first insertion groove 623 may be formed from the one surface of the first body 622 to a surface where the first body 622 is in surface-contact with the second body 625.

According to the exemplary embodiment of the present invention, four first insertion grooves 623 may be provided. However, the present invention is not limited thereto, and the number of first insertion grooves 623 may be provided in various variations. The other surface of the first body 622 that faces the one surface of the first body 622 may be in surface-contact with the second body 625. For example, the first body 622 and the second body 625 may be integrally formed.

A groove 624 is formed on one lateral surface of the first body 622. The groove 624 is formed on an external surface of the first body 622. The groove 624 provides a space in which the pin unit 640, which will be described later, is inserted. A longitudinal direction of the groove 624 may be provided parallel to a longitudinal direction of the pin unit 640. A width length of the groove 624 may correspond to a width length of the pin unit 640. The width length of the groove 624 may correspond to a sum length of the width of the pin unit 640 and a length of the width of the fuse 660 installed in the pin unit 640. Accordingly, the pin unit 640 inserted into the groove 624, and the fuse 660 installed in the pin unit 640, may not protrude from the groove 624.

The external second cable 602 may be inserted into the second body 625. The second body 625 may be formed with second insertion grooves 626 into which the external second cable 602 is inserted. In one example, four second insertion grooves 626 may be provided. However, the present invention is not limited thereto, and the number of second insertion grooves 626 may be variously modified and provided. The second body 625 may have a generally rectangular parallelepiped shape. In one example, the second body 625 may have a larger area than the first body 622 when viewed from the front.

Referring now to FIGS. 3 to 6, the pin unit 640 is detachably provided on the body 620. The pin unit 640 may be detachably provided on the first body 622. The pin unit 640 may be inserted into the groove 624 formed in the first body 622. The pin unit 640 may include a first portion 642, a second portion 644, and a third portion 646.

The first portion 642 may be provided as a conductor. The first portion 642 may be provided in a cylindrical shape. The first portion 642 may be a cylindrical shape having a first diameter. A length of the first diameter of the first portion 642 may correspond to the length of the width of the groove 624. The external first cable 601 may be inserted into the first portion 642. When the first portion 642 is inserted into the groove 624, the first portion 642 may be provided in a position corresponding to the first insertion groove 623 formed on one surface of the first body 622. Accordingly, the external first cable 601 connected to the body 620 may be connected to the pin unit 640 inserted into the groove 624. In the first portion 642, a first through-hole 643 is formed into which a first lead wire 664 of the fuse 660, which will be described later, is inserted. The fuse 660 inserted into the first through-hole 643 may be fixedly installed in the pin unit 640.

The second portion 644 may be provided as a conductor. The second portion 644 may be provided in a cylindrical shape. The second portion 644 may be a cylindrical shape having a second diameter. In one example, the second portion 644 may be provided in a cylindrical shape having the second diameter that is smaller than the first diameter of the first portion 642. By providing the second portion 644 with a different diameter from the first portion 642, the pin unit 640 may be easily removed from the body 620. Accordingly, in the event that the fuse 660 installed in the pin unit 640 becomes carbonized, the fuse 660 installed in the pin unit 640 may be easily replaced by detaching the pin unit 640 from the body 620.

The external second cable 602 may be inserted into the second portion 644. When the second portion 644 is inserted into the groove 624, the second portion 644 may be provided in a position corresponding to the second insertion groove 626 formed in the second body 625. Accordingly, the external second cable 602 connected to the body 620 may be connected to the pin unit 640 inserted into the groove 624. In the second portion 644, a second through-hole 645 is formed into which a second lead wire 666 of the fuse 660, which will be described later, is inserted. The fuse 660 inserted into the second through-hole 645 may be fixedly installed in the pin unit 640.

The third portion 646 may be located between the first portion 642 and the second portion 644. In one example, the third portion 646 may have a diameter equal to the diameter of the first portion 642. However, the present invention is not limited thereto, and the third portion 646 may be provided with a diameter equal to the diameter of the second portion 644. The third portion 646 may be provided with an insulating material. The first portion 642 and the second portion 644 may be electrically insulated by the third portion 646. Accordingly, the first cable 601 connected to the first portion 642 and the second cable 602 connected to the second portion 644 may be connected in series with each other.

The fuse 660 functions to block circuit connection due to overheating or overcurrent. The fuse 660 is detachably provided on the pin unit 640. The fuse 660 may include a fuse element 662, a first lead wire 664, and a second lead wire 666.

The fuse element 662 may electrically connect the first lead wire 664 and the second lead wire 666. One end of the fuse element 662 may be connected to the first lead wire 664. Additionally, the other end of the fuse element 662 may be connected to the second lead wire 666. The fuse element 662 may be connected in series between the first lead wire 664 and the second lead wire 666. The fuse element 662 may be a fusible element that blows due to heat and/or overcurrent generated from the first lead wire 664 and the second lead wire 666.

The fuse element 662 may be provided as a low melting point metal or alloy having a melting point of a certain temperature or lower. In one example, the fuse element 662 may be provided in a bar shape including at least one element of Sn, Ag, Al, Zn, Cu, and Ni. However, the present invention is not limited thereto, and the fuse element 662 may also include a ceramic tubular pipe, terminals formed at both ends of the tubular pipe, and a fusible wire inserted into the ceramic tubular pipe.

The first lead wire 664 may be formed at one end of the fuse element 662. The first lead wire 664 may be inserted into the first through-hole 643 formed in the first portion 642 of the pin unit 640. One end of the first lead wire 664 may be connected to the fuse element 662, and the other end of the first lead wire 664 may be inserted into the first through-hole 643 and connected to the external first cable 601 connected to the pin unit 640. The first lead wire 664 may connect the external first cable 601 and the fuse element 662 in series.

The second lead wire 666 may be formed at the other end of the fuse element 662. The second lead wire 666 may be inserted into a second through-hole 645 formed in the second portion 644 of the pin unit 640. One end of the second lead wire 666 may be connected to the fuse element 662, and the other end of the second lead wire 666 may be inserted into the second through-hole 645, so that the second lead wire 666 may be connected with the external second cable 602 connected to the pin unit 640. The second lead wire 666 may be connected in series with the external second cable 602 and the fuse element 662.

When the internal temperature of the body 620 reaches a certain temperature, the fuse element 662 may be blown by the external first cable 601 connected to the first portion 642 and the external second cable 602 connected to the second portion 644. When the fuse element 662 is blown, the first cable 601 and the second cable 602, which were connected in series via the pin unit 640 and the fuse 660, are disconnected. Thus, the circuit between the first cable 601 and the second cable 602 is disconnected, so that the current flowing to the load is eliminated, which further prevents a fire due to overheating and carbonization of the connector assembly 600. Accordingly, predetermined processes may be safely performed on the substrate W by using the substrate processing device 1.

Further, according to the exemplary embodiment of the present invention, the fuse 660 is detachably provided from the pin unit 640 to facilitate replacement of the fuse element 662 when the temperature inside the connector assembly 600 increases, or when the fuse element 662 blows due to an overcurrent being drawn to the fuse 660.

Furthermore, the pin unit 640 according to the exemplary embodiment is detachably provided from the body 620, so that when the fuse element 662 is replaced, the fuse 660 may be easily replaced by separating the pin unit 640 from the body 620 and separating the fuse 660 from the pin unit 640. Accordingly, the efficiency of maintenance of the substrate processing apparatus 1 is increased.

Furthermore, in the event of the blown fuse 660, it is not necessary to replace the entire connector assembly 600, and only the fuse 660 may be separated from the body 620 and the pin unit 640, which may significantly reduce maintenance costs.

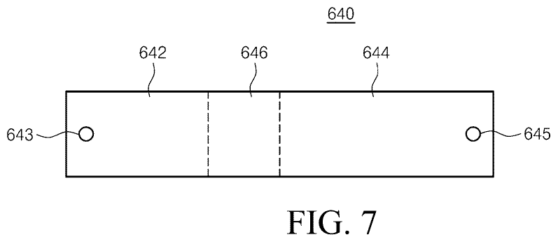

FIG. 7 is a diagram schematically illustrating the pin unit of FIG. 3 according to another exemplary embodiment. Referring to FIG. 7, the pin unit 640 is detachably provided on the body 620. The pin unit 640 may be detachably provided on the first body 622. The pin unit 640 may be inserted into the groove 624 formed in the first body 622. The pin unit 640 may include a first portion 642, a second portion 644, and a third portion 646.

The first portion 642, the second portion 644, and the third portion 646 may all be provided in a cylindrical shape. The first portion 642, the second portion 644, and the third portion 646 may all have the same diameter. The first portion 642 and the second portion 644 may be located at both ends of the pin unit 640. The third portion 646 may be located between the first portion 642 and the second portion 644. In one example, the first portion 642, the third portion 646, and the second portion 644 may be positioned sequentially from one end of the pin unit 640 to the other end. The first portion 642 and the second portion 644 may be provided as conductors. The third portion 646 may be provided with an insulating material. The first portion 642 and the second portion 644 may be electrically insulated by the third portion 646.

The external first cable 601 may be inserted into the first portion 642. When the first portion 642 is inserted into the groove 624, the first portion 642 may be provided in a position corresponding to the first insertion groove 623 formed on one surface of the first body 622. Accordingly, the external first cable 601 connected to the body 620 may be connected to the pin unit 640 inserted into the groove 624. In the first portion 642, a first through-hole 643 is formed into which a first lead wire 664 of the fuse 660, which will be described later, is inserted. The fuse 660 inserted into the first through-hole 643 may be fixedly installed in the pin unit 640.

The external second cable 602 may be inserted into the second portion 644. When the second portion 644 is inserted into the groove 624, the second portion 644 may be provided in a position corresponding to the second insertion groove 626 formed in the second body 625. Accordingly, the external second cable 602 connected to the body 620 may be connected to the pin unit 640 inserted into the groove 624. In the second portion 644, a second through-hole 645 is formed into which a second lead wire 666 of the fuse 660, which will be described later, is inserted. The fuse 660 inserted into the second through-hole 645 may be fixedly installed in the pin unit 640. The first cable 601 connected to the first portion 642 and the second cable 602 connected to the second portion 644 may be connected in series with each other by the electrically insulated third portion 646.

In the exemplary embodiments described above illustrate, the present invention is described based on the case where the connector assembly 600 is provided to the components that require power to be supplied among the components provided in the process chamber 500 as an example, but the present invention is not limited thereto. The connector assembly 600 according to the exemplary embodiment of the present invention may be provided to components included in various substrate processing apparatuses, such as components that require power to be supplied in a device that provides liquid to a substrate W for liquid treatment, components that require power to be supplied in a device that heat treats a substrate W, components that require power to be supplied in a device that transfers a substrate W, and/or components that require power to be supplied in a device that accommodates a substrate W.

The foregoing detailed description illustrates the present invention. Further, the above content illustrates and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in the specific application field and use of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a housing having a processing space for processing a substrate;
a support unit for supporting a substrate in the processing space;
a plasma source for generating plasma from process gas supplied to the processing space; and
a connector assembly provided to supply power to a component provided in the apparatus,
wherein the connector assembly includes:
a body having a groove formed on an external surface;
a pin unit inserted into the groove; and
a fuse installed in the pin unit.

2. The apparatus of claim 1, wherein the pin unit is detachably provided on the body.

3. The apparatus of claim 2, wherein the fuse is detachably provided on the pin.

4. The apparatus of claim 3, wherein the pin unit includes:
a first portion into which an external first cable is inserted; and
a second portion into which an external second cable is inserted, and
the first portion has a first through-hole into which a first lead wire of the fuse is inserted, and
the second portion has a second through-hole into which a second lead wire of the fuse is inserted.

5. The apparatus of claim 4, wherein the first portion and the second portion are provided as conductors, and
a third portion formed of an insulating material is located between the first portion and the second portion.

6. The apparatus of claim 5, wherein the first portion is provided in a cylindrical shape having a first diameter, and
the second portion is provided in a cylindrical shape having a second diameter smaller than the first diameter.

7. A connector assembly comprising:
a body having a groove formed on an external surface;
a pin unit inserted into the groove; and
a fuse installed in the pin unit,
wherein the pin unit is detachably provided on the body.

8. The connector assembly of claim 7, wherein the fuse is detachably provided on the pin unit.

9. The connector assembly of claim 8, wherein the pin unit includes:
a first portion into which an external first cable is inserted; and
a second portion into which an external second cable is inserted, and
the first portion has a first through-hole into which a first lead wire of the fuse is inserted, and
the second portion has a second through-hole into which a second lead wire of the fuse is inserted.

10. The connector assembly of claim 9, wherein the first portion and the second portion are provided as conductors, and
a third portion formed of an insulating material is located between the first portion and the second portion.

11. The connector assembly of claim 10, wherein the first portion is provided in a cylindrical shape having a first diameter, and
the second portion is provided in a cylindrical shape having a second diameter smaller than the first diameter.
